(19) United States
(12) Patent Application Publication
(10) Pub. No.: US 2022/0230677 A1
(43) Pub. Date: Jul. 21, 2022

(54) SELF-REFRESH FREQUENCY DETECTION METHOD

(71) Applicant: CHANGXIN MEMORY TECHNOLOGIES, INC., Hefei City (CN)

(72) Inventors: Bo YANG, Hefei (CN); WEI-CHOU WANG, Hefei (CN); Huanhuan LIU, Hefei (CN)

(73) Assignee: CHANGXIN MEMORY TECHNOLOGIES, INC., Hefei City (CN)

(21) Appl. No.: 17/504,875

(22) Filed: Oct. 19, 2021

Related U.S. Application Data
(63) Continuation of application No. PCT/CN2021/104923, filed on Jul. 7, 2021.

(30) Foreign Application Priority Data
Jan. 15, 2021 (CN) 202110055134.3

(51) Int. Cl. G11C 11/406; G11C 11/408; G11C 11/4076; G11C 11/4096

(52) U.S. Cl. CPC G11C 11/40615; G11C 11/40622; G11C 11/4096; G11C 11/4076; G11C 11/4085

(57) ABSTRACT

Embodiments of the present application provide a self-refresh frequency detection method, including: writing data to at least one wordline in a memory; performing a self-refresh operation on the memory; setting, after a clock enable signal changes to a low level, a duration of the low level; performing a reading operation on the memory at a positive trip point of the clock enable signal; acquiring a plurality of reading results corresponding to a plurality of durations of the low level; and obtaining a self-refresh frequency of the memory according to the plurality of durations of the low level and the plurality of reading results. The embodiments of the present application are conducive to improving the simplicity of self-refresh frequency detection.

### CROSS-REFERENCE TO RELATED APPLICATIONS

This application is a continuation of International Patent Application No. PCT/CN2021/104923 filed on Jul. 7, 2021, which claims priority to Chinese Patent Application No. 202110055134.3 filed on Jan. 15, 2021. The above-referenced patent applications are incorporated herein by reference in their entirety.

### TECHNICAL FIELD

Embodiments of the present application relate to the field of semiconductors, and in particular, to a self-refresh frequency detection method.

### BACKGROUND

A Dynamic Random Access Memory (DRAM) is currently widely used as a data storage medium in various computer systems due to advantages such as high integration and a low cost.

The DRAM works by using a state of charges stored in a capacitor to represent whether a binary bit is 1 or 0. In reality, a transistor may leak electricity either naturally or due to a hammering effect; as a result, an amount of the charges stored in the capacitor is not sufficient to correctly identify data; that is, data is lost or corrupted. Therefore, during the use of the DRAM, each memory cell is required to be refreshed periodically to prevent data loss.

A self-refresh frequency of the DRAM is critical for the DRAM.

### SUMMARY

The embodiments of the present application provide a self-refresh frequency detection method, including: writing data to at least one wordline in a memory; performing a self-refresh operation on the memory; setting, after a clock enable signal changes to a low level, a duration of the low level; performing a reading operation on the memory at a positive trip point of the clock enable signal; acquiring a plurality of reading results corresponding to a plurality of durations of the low level; and obtaining a self-refresh frequency of the memory according to the plurality of durations of the low level and the plurality of reading results.

The technical solution according to the embodiments of the present application has the following advantages.

In the above technical solution, self-refresh frequency detection is performed based on a principle that no effective reading can be performed during execution of a self-refresh operation, when a reading time of a reading operation enters or exceeds an execution time period of the self-refresh operation, a reading result corresponding to the reading time may be changed accordingly, and a self-refresh cycle and a self-refresh frequency of the self-refresh operation can be obtained according to the corresponding reading time of the changed reading result. The detection principle of the above detection method is universal in different memory granules, so the detection method can be applied to detection of different memory granules. A production line tester is not required to know special test modes corresponding to different memory granules and configured to output self-refresh frequencies, which is conducive to improving the simplicity of the self-refresh frequency detection.

In addition, preset time is greater than a sum of one self-refresh cycle and a duration of one self-refresh operation, which is conducive to obtaining the self-refresh cycle and the self-refresh frequency through first and second second-type reading conversion moments in a case where the reading operation is delayed.

### BRIEF DESCRIPTION OF DRAWINGS

One or more embodiments are exemplarily described by using figures that are corresponding thereto in the accompanying drawings; the exemplary descriptions do not constitute limitations on the embodiments. Unless otherwise particularly stated, the figures in the accompanying drawings do not constitute a scale limitation.

FIG. 1 is a schematic flowchart of a self-refresh frequency detection method according to an embodiment of the present application; and

FIG. 2 is a schematic logic diagram of a self-refresh frequency detection method according to an embodiment of the present application.

### DESCRIPTION OF EMBODIMENTS

During current memory granule detection, test objects may include different types of memory granules from a same manufacturer or different types of memory granules from different manufacturers. In a case where a specific circuit design of a memory granule is not known, a self-refresh frequency of the memory granule can be acquired generally by entering a special test mode corresponding to the memory granule and configured to output a self-refresh frequency. However, in an actual test scenario, the production line tester generally cannot accurately grasp the specific test mode corresponding to each memory granule.

In order to solve the above problem, an embodiment of the present application provides a self-refresh frequency detection method, in which self-refresh frequency detection is performed based on a principle that no effective reading can be performed during execution of a self-refresh operation, when a reading time of a reading operation enters or exceeds an execution time period of the self-refresh operation, a reading result corresponding to the reading time may be changed accordingly, and a self-refresh cycle and a self-refresh frequency of the self-refresh operation can be obtained according to the corresponding reading time of the changed reading result. The detection principle of the above detection method is universal in different memory granules, so the detection method can be applied to detection of different memory granules. A production line tester is not required to know special test modes corresponding to different memory granules and configured to output self-refresh frequencies, which is conducive to improving the simplicity of the self-refresh frequency detection.

In order to make objectives, technical solutions and advantages of the embodiments of the present application clearer, various embodiments of the present application will be described below in detail with reference to the drawings. However, those of ordinary skill in the art may understand that, in the embodiments of the present application, numerous technical details are set forth in order to enable a reader to better understand the present application. However, the technical solutions claimed in the present application can be implemented without these technical details and various changes and modifications based on the embodiments below.

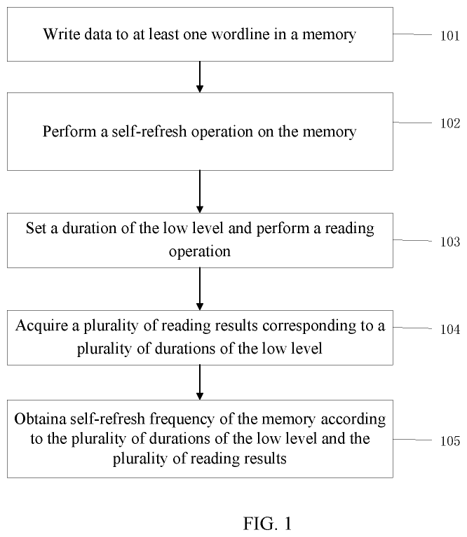

FIG. 1 is a schematic flowchart of a self-refresh frequency detection method according to an embodiment of the present application. Specifically, the self-refresh frequency detection method includes the following steps.

In step 101, data is written to at least one wordline in a memory.

The memory generally includes a plurality of memory banks each including a plurality of wordlines. In this embodiment, when data is written for subsequent reading and writing, each memory bank in the memory is activated, and the data is sequentially written to all the wordlines in each memory bank until the entire memory is filled with preset data. In other embodiments, data writing is performed on only one wordline in a certain memory bank.

Specifically, the step of writing data to all wordlines in each memory bank may be specifically as follows: selecting a memory bank and activating one wordline therein, and writing preset data to the entire wordline; after the preset data is fully written, deactivating the current wordline and activating another wordline, and rewriting the preset data until the another wordline is filled; repeating the above operations until all the wordlines in a memory bank of the memory are filled; in this case, selecting another memory bank and activating one wordline therein for data writing until the wordline is filled; and repeating the above operation until the wordlines in all the memory banks of the memory are filled with the preset data.

A writing order of the memory banks in the memory and a writing order of the wordlines in the memory banks are random. Secondly, the preset data may be a binary bit “1”, so that a reading result is considered as a failure when a subsequent reading result is 0 or no effective reading result is obtained.

In step 102, a self-refresh operation is performed on the memory.

The self-refresh operation on the memory is equivalent to sending an activation command to the memory so that the self-refresh operation is performed after a clock enable signal changes to a low level. The clock enable signal (CKE signal) is a low-level valid signal. In a case where the clock enable signal is at a low level, a self-refresh operation of a memory bank, a memory or a memory granule can be performed normally; that is, the low level of the clock enable signal is configured to trigger a self-refresh operation of a memory bank.

In this embodiment, prior to a subsequent duration definition operation and a subsequent reading operation, at least one wordline to which the data is written is refreshed, or precisely, automatically refreshed, so as to ensure that a sufficient amount of charges is stored in a capacitor connected to each wordline, which helps prevent data loss caused by electricity leakage during the self-refresh frequency detection and ensures the accuracy of the reading result.

In step 103, a duration of the low level is set and a reading operation is performed.

In this embodiment, after the clock enable signal of the memory bank changes to a low level, a duration definition operation is performed to define the duration of the low level; that is, the low level of the clock enable signal is maintained for “the duration” and then changes to a high level; at the same time, the self-refresh operation within the duration is in an execution state.

The clock enable signal has a “positive trip point” which is a time point of a jump from a low level to a high level. The “positive trip point” is at a high level. It is to be noted that although the “positive trip point” is at a high level, since the jump has just been completed, the self-refresh operation is still executable at the “positive trip point”. That is, at the moment of the “positive trip point”, the reading operation cannot be effectively performed, but after the “positive trip point”, the reading operation may be effectively performed.

The reading operation cannot be effectively performed within the execution time period of the self-refresh operation 10. Specifically, the reading operation can only perform a reading action on the wordline when the capacitor connected to the wordline is in a refresh stage; however, since the wordline cannot be activated, the reading operation cannot be completed effectively due to an error, and the reading result of the read operation is considered as a failure. Further, when a reading result of a reading operation at a previous moment is Success and a reading result of a reading operation at a subsequent moment is Failure, the subsequent moment may be considered as a starting time point of the self-refresh operation 10; in this case, the self-refresh operation 10 is started or is ongoing. When the reading result of the reading operation at the previous moment is Failure and the reading result of the reading operation at the subsequent moment is Success, the subsequent moment may be considered as an ending time point of the self-refresh operation 10; in this case, the self-refresh operation 10 has ended.

In this embodiment, the reading operation includes a plurality of sequential reading actions, and a reading action is continuously performed on at least one wordline at least within the duration of the low level. Specifically, when data is written to only one wordline, the data of the wordline is continuously read through the reading action; when all wordlines in all memory banks are filled with data, reading is performed randomly through the reading action; that is, the memory banks in the memory and the wordlines in the memory banks are read randomly. The memory banks in the memory and the wordlines in the memory banks may also be read sequentially.

The reading action continuously performed is configured to read data of different wordlines, which helps prevent damages to data in a single wordline caused by continuous reading; that is, the capacitor continues to discharge so that the amount of charges is not sufficient to correctly identify the data. Furthermore, the reading result can be ensured to effectively represent whether the self-refresh operation 10 is ongoing. It is to be noted that even reading data from different wordlines is required to be completed within reasonable time; otherwise, the capacitor may have insufficient charges due to natural leakage.

In addition, a same wordline may be read effectively and continuously within the reasonable time. Beyond the time period, write-back is required to ensure the accuracy of the data.

In this embodiment, the reading operation includes a plurality of sequential reading actions, but one reading operation corresponds to only one reading time and one reading result. When a reading result of any of the reading actions is Failure, the reading result of the reading operation is Failure. Further, reading time corresponding to the reading operation is set to a duration set for the duration definition operation. Reading is performed at the positive trip point of the clock enable signal through the reading operation. In this way, a reading result can effectively indicate whether the positive trip point is within a time period occupied by the self-refresh operation; that is, validity of a corresponding relationship between reading time and reading results is ensured.

For example, when the duration of the low level is 1800 ns, the duration of the low level ranges from 0 to 1800 ns, and the reading time of the reading operation is set to 1800 ns. The set reading time is the positive trip point of the clock enable signal. When the moment 1700 ns is within the execution time period of the self-refresh operation 10 and the moment 1800 ns is between execution time periods of adjacent self-refresh operations 10, if the reading operation starts at 1800 ns, the reading result of the reading operation is Success, and a corresponding relationship between the reading time and the reading result can be obtained: the moment 1800 ns corresponds to successful reading, and this corresponding relationship is correct. If reading actually starts at 1700 ns, the reading result is Failure; that is, an actually-obtained corresponding relationship between the reading time and the reading result is that the moment 1800 ns corresponds to failed reading, and an error occurs in the corresponding relationship. Therefore, in order to ensure a correct corresponding relationship between the reading time and the reading result, an actual starting time point of the reading operation should be as close as possible to the positive trip point of the clock enable signal.

The time point after the positive trip point is at a high level, the self-refresh operation 10 may not be triggered, and the reading result of the reading operation is definitely Success; therefore, the reading result of the reading operation performed at the positive trip point depends entirely on whether the positive trip point is within the execution period of the self-refresh operation 10. That is, whether a reading operation starting at the positive trip point includes only one reading action or a plurality of reading actions, a reading result of the reading operation is not affected.

Further, since the reading result of the reading operation depends only on a reading result of the reading action performed at the positive trip point and is independent of other reading actions, the reading result corresponding to the reading operation is not affected by time intervals between adjacent reading actions. The time intervals between adjacent reading actions may be equal or unequal. The time intervals between adjacent reading actions are correlated with how the reading actions are executed. For example, bursting continuous reading results in different time intervals between adjacent reading actions.

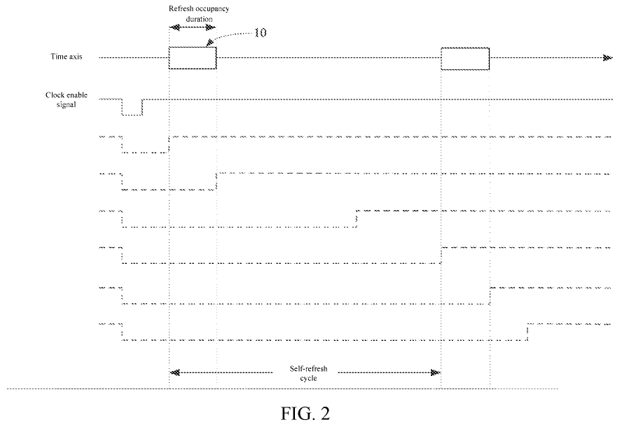

Referring to FIG. 2, the self-refresh operation 10 has a self-refresh cycle, and a reciprocal of the self-refresh cycle is a self-refresh frequency. The self-refresh operation 10 has a refresh occupancy duration which is a duration required by the memory bank to complete refresh. In order to acquire the self-refresh cycle, starting time points or ending time points of adjacent self-refresh operations 10 are required to be acquired, so as to obtain a refresh time interval of the self-refresh operations 10 according to a difference between the starting time points or ending time points, thereby acquiring the self-refresh frequency.

In step 104, a plurality of reading results corresponding to a plurality of durations of the low level are acquired.

In order to acquire a plurality of reading results, the duration definition operation and the reading operation are required to be performed alternately. Specifically, a duration set for a subsequent duration definition operation is greater than that set for a previous duration definition operation, and durations of the low level set for adjacent duration definition operations may be at an interval of 50 ns to 150 ns.

Further, the duration definition operation may be repeated multiple times, until the duration set for the duration definition operation is greater than a preset duration. Ideally, the preset duration may be set to be greater than one self-refresh cycle to acquire starting time points of two self-refresh operations 10 triggered first and then obtain the self-refresh cycle and the self-refresh frequency. In practice, the preset duration may be set to be greater than a sum of one self-refresh cycle and one refresh occupancy duration, so as to ensure that ending time points of the two self-refresh operations 10 triggered first can be acquired when the reading operation is delayed, thereby obtaining the self-refresh cycle and the self-refresh frequency.

Specific values are provided below for illustration. It is assumed that the refresh occupancy duration of the self-refresh operation 10 is 600 ns and the self-refresh cycle is 7 μs, a time point at which the clock enable signal changes to a low level is taken as time axis zero, and a starting time point of the first self-refresh operation 10 triggered is 1100 ns.

Since the refresh occupancy duration is 600 ns, the time period from 1100 ns to 1700 ns is the execution time period of the self-refresh operation 10, and no reading operation can be performed within the time period. Further, since the self-refresh cycle is 7 μs, a starting time point of the second self-refresh operation 10 triggered is 8100 ns, the execution time period of the second self-refresh operation 10 ranges from 8100 ns to 8700 ns, and no reading operation can be performed within the time period.

Assume that the durations of the low level set for adjacent duration definition operations are at an interval of 100 ns, reading results of 10 reading operations performed within 100 ns to 1000 ns are Success, reading results of 7 reading operations performed within 1100 ns to 1700 ns are Failure, reading results of 63 reading operations performed within 1800 ns to 8000 ns are Success, reading results of 7 reading operations performed within 8100 ns to 8700 ns are Failure, and a reading result of the reading operation performed at 8800 ns is Success.

A reading moment of conversion from successful reading to failed reading is recorded as a first-type reading conversion moment which corresponds to the starting time point of the self-refresh operation 10, for example, 1100 ns and 8100 ns. A reading moment of conversion from failed reading to successful reading is recorded as a second-type reading conversion moment which corresponds to the ending time point of the self-refresh operation 10, for example, 1800 ns and 8800 ns.

In this embodiment, the duration of the low level of the clock enable signal is greater than one self-refresh cycle, and a self-refresh cycle and a self-refresh frequency of a memory bank are obtained according to adjacent first-type reading conversion moments. In other embodiments, a starting moment of the reading operation is delayed relative to a moment at which the clock enable signal changes to a low level. This delay may be caused by a delay in the sending of a reading signal or the existence of the duration definition operation, which causes an actual starting moment of the reading operation to be within the execution period of the first self-refresh operation 10, for example, within 1100 ns to 1700 ns. This results in that some reading operations are not actually performed until the clock enable signal changes to a high level, so that reading results corresponding to some durations of the low level are definitely Success, even if the positive trip point is within the execution time period of the first self-refresh operation 10.

In other words, when an actual starting moment of the reading operation is within the execution time period of the first self-refresh operation 10, the first first-type reading conversion moment is invalid, and an actually valid first-type reading conversion moment is the first second-type reading conversion moment. In this case, the self-refresh cycle and the self-refresh frequency of the memory bank can be obtained according to adjacent second-type reading conversion moments. Correspondingly, the duration of the low level in this case should be greater than a sum of one self-refresh cycle and a refresh occupancy duration of one self-refresh operation, so as to ensure that the two adjacent second-type reading conversion moments are within the duration of the low level.

It is to be noted that the above values are only illustrative. In other embodiments, the refresh occupancy duration of the self-refresh operation may also be other values, such as 500 ns, the self-refresh cycle may also be other values, such as 3.9 μs, and the difference between durations may also be other values between 50 ns and 150 ns, such as 60 ns, 80 ns, 120 ns, or 140 ns.

In step 105, a self-refresh frequency of the memory is obtained according to the plurality of durations of the low level and the plurality of reading results.

In this embodiment, the duration definition operation and the reading operation are performed multiple times to acquire a plurality of reading times and a plurality of reading results corresponding to the multiple reading operations and then obtain the self-refresh cycle and the self-refresh frequency of the memory bank.

In this embodiment, self-refresh frequency detection is performed based on a principle that no effective reading can be performed during execution of a self-refresh operation, when a reading time of a reading operation enters or exceeds an execution time period of the self-refresh operation, a reading result corresponding to the reading time may be changed accordingly, and a self-refresh cycle and a self-refresh frequency of the self-refresh operation can be obtained according to the corresponding reading time of the changed reading result. The detection principle of the above detection method is universal in different memory granules, so the detection method can be applied to detection of different memory granules. A production line tester is not required to know special test modes corresponding to different memory granules and configured to output self-refresh frequencies, which is conducive to improving the simplicity of the self-refresh frequency detection.

Those of ordinary skill in the art may understand that the above implementations are specific embodiments for implementing the present application. However, in practical applications, various changes in forms and details may be made thereto without departing from the spirit and scope of the present application. Any person skilled in the art can make respective changes and modifications without departing from the spirit and scope of the present application. Therefore, the protection scope of the present application should be subject to the scope defined by the claims.

What is claimed is:

1. A self-refresh frequency detection method, comprising:
writing data to at least one wordline in a memory;
performing a self-refresh operation on the memory;
setting, after a clock enable signal changes to a low level, a duration of the low level;
performing a reading operation on the memory at a positive trip point of the clock enable signal;
acquiring a plurality of reading results corresponding to a plurality of durations of the low level; and
obtaining a self-refresh frequency of the memory according to the plurality of durations of the low level and the plurality of reading results.

2. The self-refresh frequency detection method according to claim 1, wherein the setting of the duration of the low level and the reading operation are performed alternately.

3. The self-refresh frequency detection method according to claim 1, wherein the reading operation comprises a plurality of sequential reading actions, and when a reading result of any of the reading actions is Failure, the reading result of the reading operation is Failure.

4. The self-refresh frequency detection method according to claim 1, wherein the setting of the duration of the low level comprises a subsequent duration of the low level being greater than a previous duration of the low level.

5. The self-refresh frequency detection method according to claim 4, wherein a difference between any two adjacent durations of the low level is equal.

6. The self-refresh frequency detection method according to claim 5, wherein a difference between the durations ranges from 50 ns to 150 ns.

7. The self-refresh frequency detection method according to claim 4, wherein the duration of the low level is continuously set until the duration of the low level is greater than a preset duration.

8. The self-refresh frequency detection method according to claim 7, wherein the preset duration is greater than a self-refresh cycle, and the self-refresh cycle is a reciprocal of the self-refresh frequency.

9. The self-refresh frequency detection method according to claim 1, wherein the reading result comprises a first-type reading conversion moment, the first-type reading conversion moment being a reading moment of conversion from successful reading to failed reading; and the self-refresh frequency of the memory is obtained according to two adjacent first-type reading conversion moments.

10. The self-refresh frequency detection method according to claim 9, wherein the self-refresh cycle comprises 7 μs to 3.9 μs.

11. The self-refresh frequency detection method according to claim 7, wherein the preset duration is greater than a sum of one self-refresh cycle and a duration of one self-refresh operation, and the self-refresh cycle is a reciprocal of the self-refresh frequency.

12. The self-refresh frequency detection method according to claim 1, wherein the reading result comprises a second-type reading conversion moment, the second-type reading conversion moment being a reading moment of conversion from failed reading to successful reading; and the self-refresh frequency of the memory is obtained according to two adjacent second-type reading conversion moments.

13. The self-refresh frequency detection method according to claim 12, wherein the duration of the self-refresh operation comprises 600 ns.

14. The self-refresh frequency detection method according to claim 1, wherein the data is sequentially written to all wordlines prior to the setting of the duration of the low level; and the reading operation is used to sequentially read all the wordlines in the memory.

15. The self-refresh frequency detection method according to claim 1, wherein the data is sequentially written to all memory banks prior to the setting of the duration of the low level; and the reading operation is used to sequentially read all the memory banks.

16. The self-refresh frequency detection method according to claim 8, wherein the reading result comprises a first-type reading conversion moment, the first-type reading conversion moment being a reading moment of conversion from successful reading to failed reading; and the self-refresh frequency of the memory is obtained according to two adjacent first-type reading conversion moments.

17. The self-refresh frequency detection method according to claim 16, wherein the self-refresh cycle comprises 7 μs to 3.9 μs.

18. The self-refresh frequency detection method according to claim 11, wherein the reading result comprises a second-type reading conversion moment, the second-type reading conversion moment being a reading moment of conversion from failed reading to successful reading; and the self-refresh frequency of the memory is obtained according to two adjacent second-type reading conversion moments.

19. The self-refresh frequency detection method according to claim 14, wherein the data is sequentially written to all memory banks prior to the setting of the duration of the low level; and the reading operation is used to sequentially read all the memory banks.
